(19) United States
(12) Patent Application Publication
(10) Pub. No.: US 2015/0216069 A1
(43) Pub. Date: Jul. 30, 2015

(54) INFORMATION PROCESSING APPARATUS AND REPLACEMENT UNIT

(71) Applicant: FUJITSU LIMITED, Kawasaki-shi (JP)

(72) Inventor: Kazunori Hori, KAWASAKI (JP)

(21) Appl. No.: 14/591,027

(22) Filed: Jan. 7, 2015

(30) Foreign Application Priority Data
Jan. 28, 2014 (JP) 2014-013298

(51) Int. Cl. H05K 7/14; H05K 7/20; H05K 7/18

(52) U.S. Cl. CPC H05K 7/1417; H05K 7/183; H05K 7/20554

(57) ABSTRACT

A disclosed information processing apparatus includes: an enclosure; a plurality of replacement units each provided inside the enclosure and including a component and a joint bendably coupled to each other; and a plurality of guide rails which are provided inside the enclosure for each of the plurality of replacement units and to which the replacement unit is fitted.

### CROSS-REFERENCE TO RELATED APPLICATION

This application is based upon and claims the benefit of priority of the prior Japanese Patent Application No. 2014-013298, filed on Jan. 28, 2014, the entire contents of which are incorporated herein by reference.

### FIELD

The embodiments discussed herein are related to an information processing apparatus and a replacement unit.

### BACKGROUND

In data centers and similar facilities, information processing apparatuses such as servers constantly process information to respond various processing requests. In order to increase the availability of such servers, the servers are preferably operated for a long period of time without being stopped and, ideally, the servers are operated continuously 24 hours, 365 days.

In case of a failure of a component of a server, that component is replaced. Here, stopping the server for the replacement work lowers the availability of the server. Replacement work of a component without stopping a server is called active maintenance. If a server may be provided with replacement units as components which allow active maintenance, the availability of the server may be increased.

### SUMMARY

According to one aspect of the following disclosure, there is provided an information processing apparatus, including: an enclosure; a plurality of replacement units each provided inside the enclosure and including a component and a joint bendably coupled to each other; and a plurality of guide rails which are provided inside the enclosure for each of the plurality of replacement units and to which the replacement unit is fitted.

According to another aspect of the disclosure, there is provided a replacement unit, including: a component; a joint bendably provided to the component; and a protrusion provided to at least one of the component and the joint and configured to be fitted to a guide rail of an information processing apparatus.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a perspective view of an information processing apparatus which the inventor of the present application has considered;

FIG. 2 is a perspective view of another information processing apparatus which the inventor of the present application has considered;

FIG. 3 is a perspective view of an information processing apparatus according to a first embodiment;

FIG. 4 is a perspective view of replacement units and their peripheral parts according to the first embodiment;

FIG. 5 is a perspective view of a back panel as seen from second connectors side in the first embodiment;

FIG. 6 is an exploded perspective view of one of the replacement units and its peripheral parts according to the first embodiment;

FIG. 7 is an enlarged perspective view of corner portions of guide rails according to the first embodiment;

FIG. 8 is a cross-sectional view of a fan according to the first embodiment;

FIG. 9 is a top view of the replacement units according to the first embodiment;

FIG. 10 is a top view of the replacement units and the guide rails according to the first embodiment;

FIGS. 11A to 11E are plan views for describing a method of replacing a replacement unit according to the first embodiment;

FIG. 12 is a view schematically illustrating forces applied to parts of the replacement units when the replacement units are pushed into an enclosure in the first embodiment;

FIG. 13 is a perspective view of an information processing apparatus according to a second embodiment;

FIG. 14 is a top view of the information processing apparatus without upper guide rails in the second embodiment;

FIG. 15 is a perspective view of an information processing apparatus according to a third embodiment;

FIG. 16 is a side cross-sectional view of part of the information processing apparatus according to the third embodiment;

FIG. 17 is a side cross-sectional view of part of the information processing apparatus without one of two guide rails provided to each replacement unit in the third embodiment;

FIG. 18 is a perspective view of replacement units and their peripheral parts according to a fourth embodiment;

FIG. 19 is a front view of the replacement units according to the fourth embodiment;

FIG. 20 is a perspective view of a grip part according to the fourth embodiment;

FIG. 21 is a perspective view of the grip part according to the fourth embodiment as seen from a different angle from FIG. 20;

FIG. 22 is an enlarged perspective view of the information processing apparatus according to the fourth embodiment;

FIG. 23 is an enlarged side view of a replacement unit according to a fifth embodiment;

FIG. 24 is an enlarged side view of the replacement unit with its lever turned by the operator in the fifth embodiment; and

FIG. 25 is a perspective view of an information processing apparatus according to a sixth embodiment.

### DESCRIPTION OF EMBODIMENTS

Prior to description of embodiments, matters which the inventor of the present application has considered will be described.

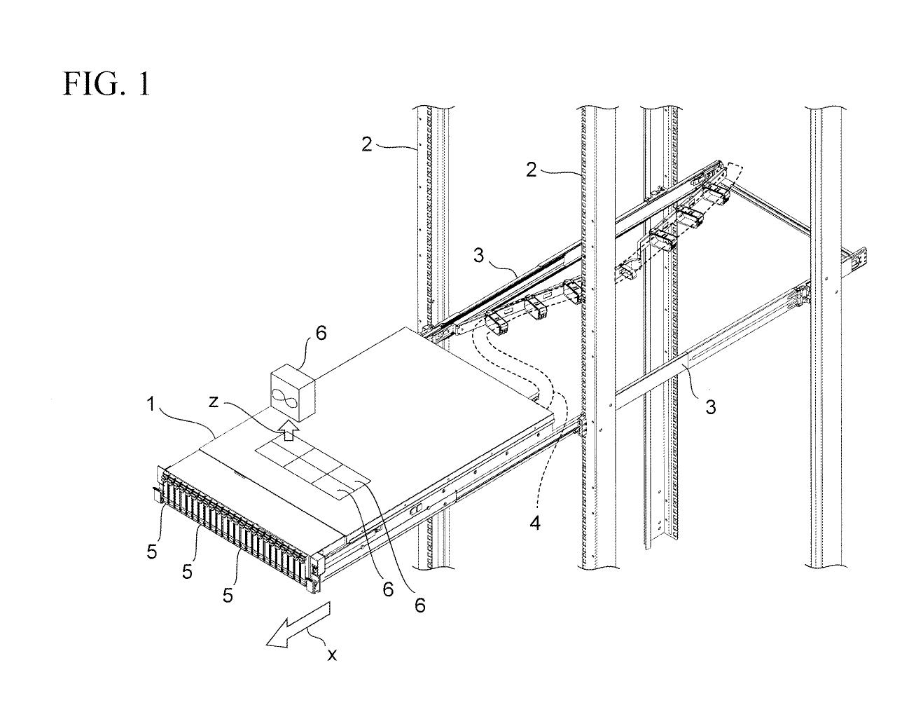

FIG. 1 is a perspective view of an information processing apparatus which the inventor of the present application has considered.

This information processing apparatus 1 is, for example, a server and housed in a rack 2. The information processing apparatus 1 is provided with components such as a plurality of fans 6 and a plurality of hard disks 5. These components are replaced in case of a failure or the like.

Moreover, a cable 4 is connected to the back face side of the information processing apparatus 1. The cable 4 is configured to supply electric power to the fans 6 and the hard disks 5 and transfer input-output signals of these components to other information processing apparatuses.

Further, rails 3 are provided to the rack 2. The operator pulls out the information processing apparatus 1 along these rails 3 in the direction of an arrow X, and performs maintenance on the information processing apparatus 1. This example assumes a case where the operator takes out one of the fans 6 in the direction of an arrow Z and replaces that fan 6 with a new one.

By making the information processing apparatus 1 movable along the rails 3 as described above, the operator may pull out the information processing apparatus 1 to an easily workable position and easily replace the fan 6.

However, the cable 4 has a certain length to make the information processing apparatus 1 capable of being pulled out, which causes delays in signals transferred through the cable 4. In this case, a problem arises in that fast signal communications are not performed between the information processing apparatus 1 and other information processing apparatuses.

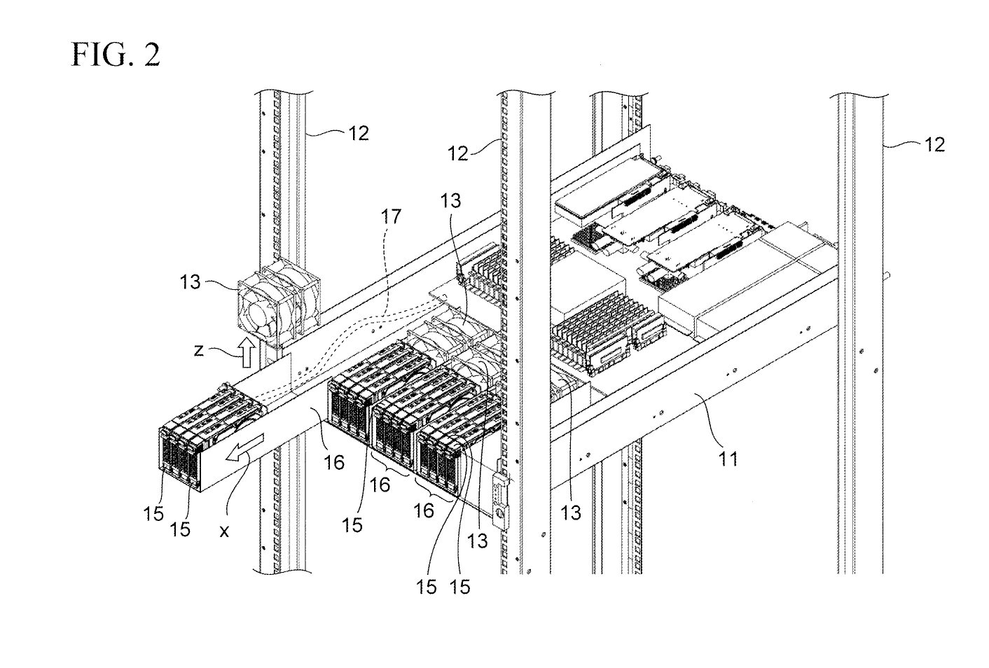

FIG. 2 is a perspective view of another information processing apparatus which the inventor of the present application has considered to solve this problem.

This information processing apparatus 11 is also a server and fixed to a rack 12. The information processing apparatus 11 houses a plurality of fans 13 and a plurality of hard disks 15. In this example, the fans 13 and the hard disks 15 are separated and grouped by a predetermined number, and a drawer part 16 is provided for each group.

The drawer parts 16 are electrically connected by a cable 17. The cable 17 is used, for example, to supply electric power to the fans 13 and the hard disks 15 and transfer input-output signals of these components.

In this example, by pulling out a drawer part 16 mentioned above in the direction of an arrow X, the fans 13 housed in the drawer part 16 may be taken out in the direction of an arrow Z, and the fans 13 may be replaced with new ones.

Further, since the whole information processing apparatus 11 is not pulled out of the rack 12 for replacement of fans 13, signal communications between a plurality of information processing apparatuses do not slow down due to the length of the cable 4 as in the example of FIG. 1.

Still, the cable 17 has a certain length to make each drawer part 16 capable of being pulled out. Signal delays occur inside one information processing apparatus 11 due to that length of the cable 17.

Hereinbelow, embodiments capable of both prevention of these signal delays and active maintenance of an information processing apparatus will be described.

### First Embodiment

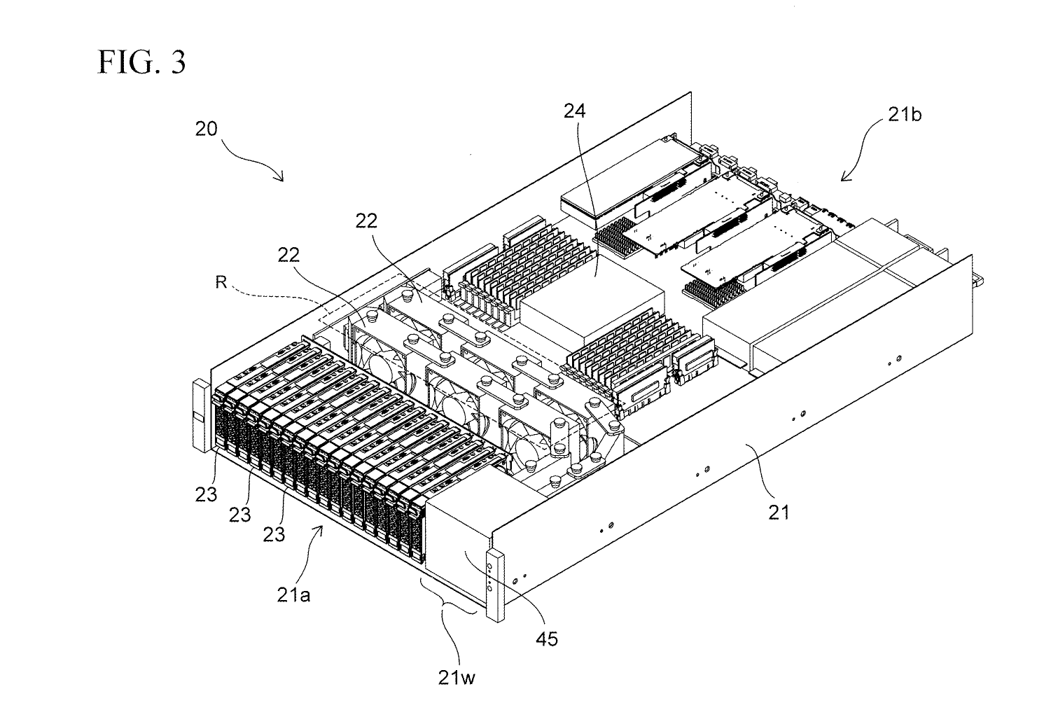

FIG. 3 is a perspective view of an information processing apparatus according to this embodiment.

This information processing apparatus 20 is, for example, a server and includes an enclosure 21 and replacement units 22 housed therein.

Each replacement unit 22 is a unit of components to be replaced and is a set of fans in this example.

An opening 21w in which a cover 45 is fitted is formed on a front face 21a side of the enclosure 21. For replacement of a replacement unit 22 mentioned above, this cover 45 is removed and that replacement unit 22 is pulled out of the enclosure 21 and a new one is inserted into the enclosure 21 through the opening 21w.

Note that the cover 45 is made of metal and has a function of preventing electromagnetic waves generated inside the enclosure 21 from leaking to the outside of the enclosure 21.

Further, a plurality of hard disks 23 are provided on the front face 21a side of the enclosure 21. A gap is present between each adjacent two hard disks 23, and the replacement units 22 mentioned above are configured to suck cooling air through the gaps. Meanwhile, the hard disks 23 may be provided with a frame having holes therein, and cooling air may be sucked through these holes. The cooling air cools an electronic component 24 such as a CPU provided inside the enclosure 21, and is then discharged from a back face 21b of the enclosure 21.

In this embodiment, two replacement units 22 are provided at a front row and a rear row as seen from the front face 21a side in such a way that these replacement units 22 face each other in a partial region R. In this way, even when one of the two replacement units 22 is removed from the enclosure 21, the electronic component 24 may be cooled by cooling air generated by the other replacement unit 22. Thus, active maintenance of the information processing apparatus 20 is possible.

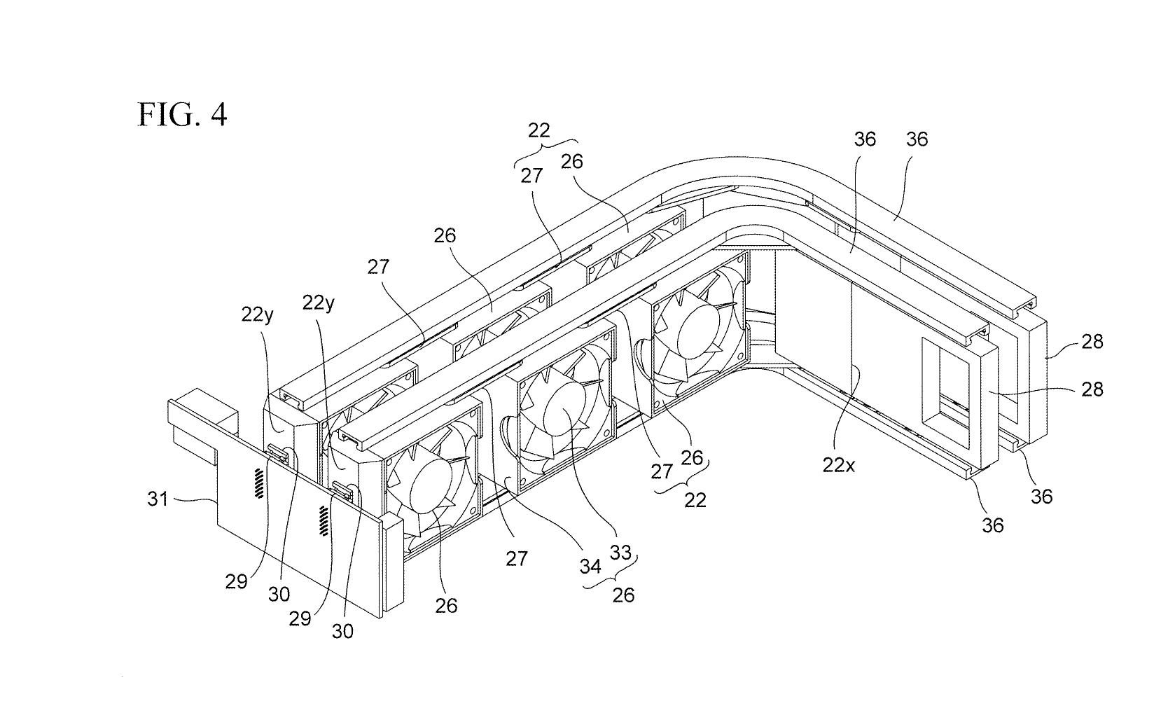

FIG. 4 is a perspective view of the replacement units 22 and their peripheral parts.

As illustrated in FIG. 4, each replacement unit 22 includes a plurality of fans 26 and a plurality of joints 27 bendably coupled to each other. Note that each fan 26 is an example of a component.

Each fan 26 includes a body 33 and a housing 34 configured to house the body 33, and has a square shape measuring about 40 mm to 80 mm in length on each side in a plan view. Note that the size of the fan 26 is not limited to this, and a fan 26 of any size suitable for the information processing apparatus 20 may be used.

Moreover, guide rails 36 bent in a substantially L-shape are provided on the upper and lower sides of each replacement unit 22. The guide rails 36 are fixed to the enclosure 21 (FIG. 3), and the replacement unit 22 is movable along the guide rails 36.

In this example, one straight portion of each substantially L-shaped guide rail 36 is arranged in parallel with the front face 21a (see FIG. 3) of the enclosure 21, while the other straight portion is arranged perpendicularly to the front face 21a.

In addition, a grip part 28 for the user to grip is provided at a proximal end 22x of each replacement unit 22.

Moreover, there is provided a back panel 31 fixed to the enclosure 21 (see FIG. 3) on a distal end 22y side of the replacement unit 22. First connectors 29 are fixed to the back panel 31. Also, second connectors 30 configured to be fitted to these first connectors 29 are provided on the distal ends 22y of the replacement units 22.

The connectors 29, 30 are detachably attachable to each other, and electric power for driving the fans 26 is supplied to the replacement units 22 through these connectors 29, 30.

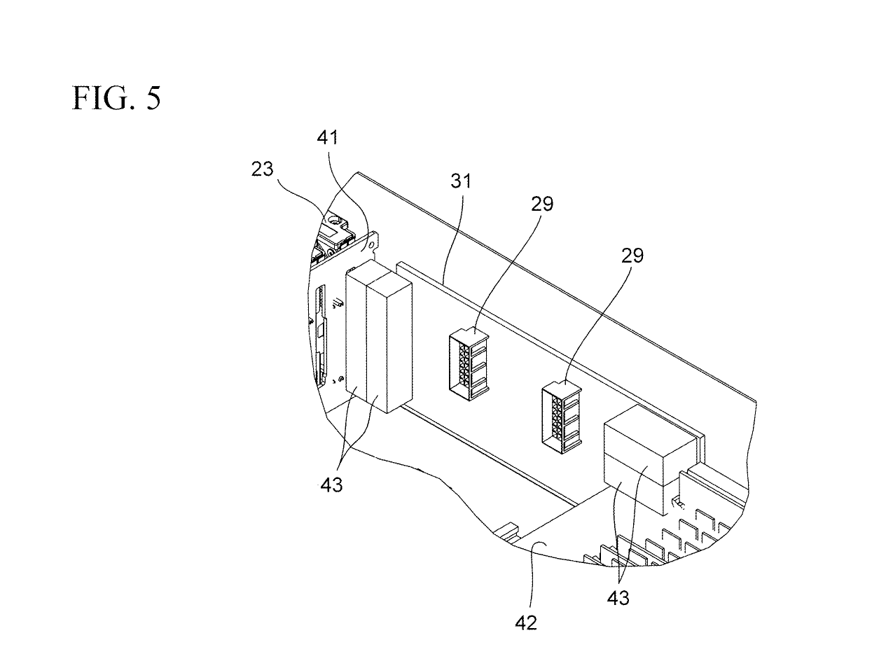

FIG. 5 is a perspective view of the back panel 31 as seen from the second connectors 30 side.

As illustrated in FIG. 5, a hard disk board 41 and a mother board 42 are provided beside the back panel 31.

Among them, the hard disk board 41 is a circuit board configured to supply electric power to the plurality of hard disks 23 and exchange input-output signals to and from the hard disks 23. Moreover, the mother board 42 is a circuit board configured to exchange input-output signals to and from the electronic component 24 (see FIG. 3).

Also, the back panel 31 is connected to the hard disk board 41 and the mother board 42 by connectors 43.

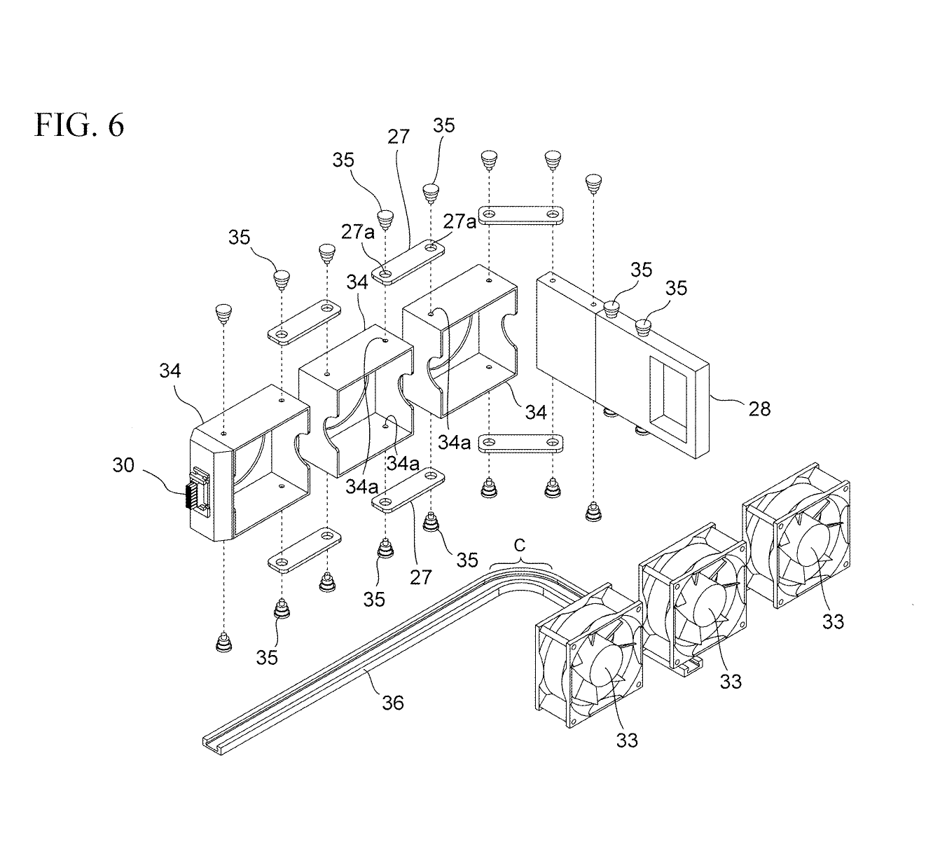

FIG. 6 is an exploded perspective view of one of the replacement units 22 and its peripheral parts.

As illustrated in FIG. 6, threaded holes 34a are bored through each housing 34, and openings 27a are formed through each joint 27 at positions corresponding to these threaded holes 34a. Moreover, guide protrusions 35 are inserted in the openings 27a and the threaded holes 34a. A thread groove is formed in a tip portion of each of the guide protrusions 35. Thus, the guide protrusions 35 are fixed to the housing 34 when their thread grooves and the threaded holes 34a are fitted to each other.

The guide protrusions 35 are fitted to the guide rails 36. This allows the replacement units 22 to be guided along the guide rails 36.

Note that in this example, the guide rails 36 are rounded at their corner portions C so that the guide protrusions 35 may move smoothly at the corner portions C.

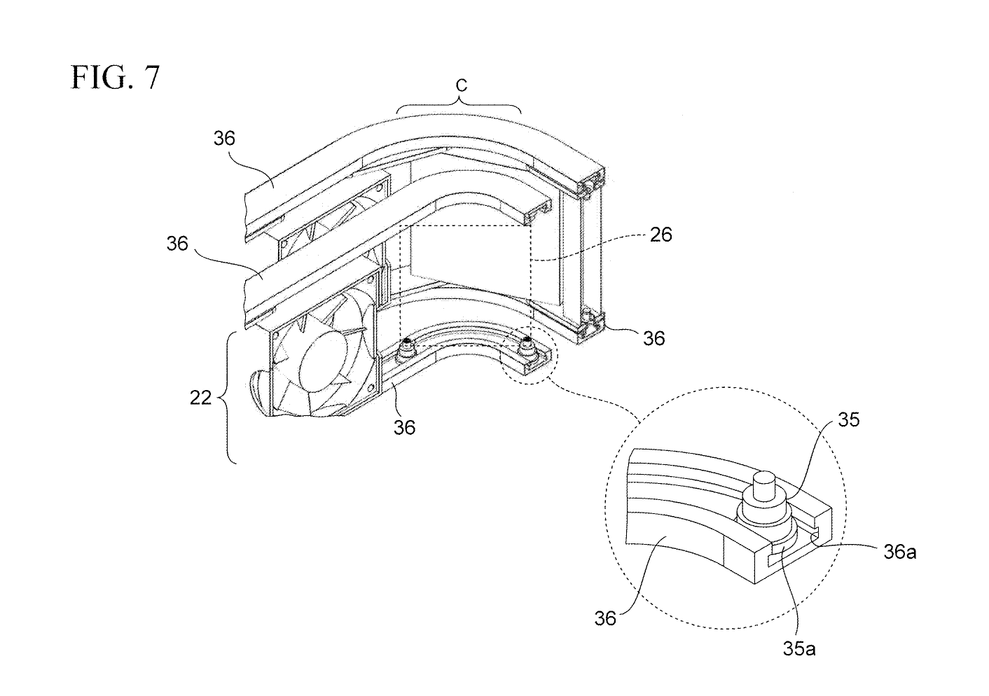

FIG. 7 is an enlarged perspective view of the corner portions C of the guide rails 36.

As illustrated inside the dotted circle in FIG. 7, an expanded portion 35a is formed on each guide protrusion 35, and this expanded portion 35a is fitted to grooves 36a in the corresponding guide rail 36. In this way, the guide protrusion 35 is prevented from being displaced from the guide rail 36.

Moreover, two guide rails 36 are arranged on the upper and lower sides of one replacement unit 22, and the replacement unit 22 is sandwiched between the upper and lower guide rails 36. In this way, the posture of the replacement unit 22 is stabilized, and the replacement unit 22 may therefore move smoothly along the upper and lower guide rails 36.

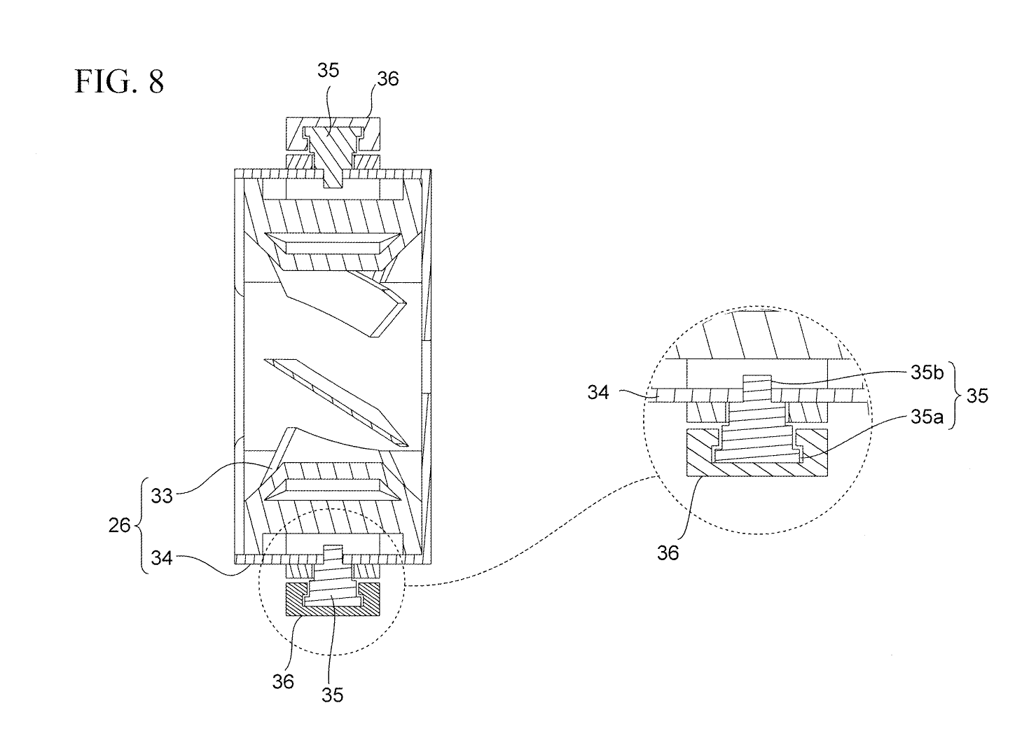

FIG. 8 is a cross-sectional view of one of the fans 26.

As illustrated inside the dotted circle in FIG. 8, a tip portion 35b of each guide protrusion 35 is fixed to the housing 34 while the expanded portion 35a is situated outside the housing 34.

Next, preferable dimensions of the replacement units 22 and the guide rails 36 will be described.

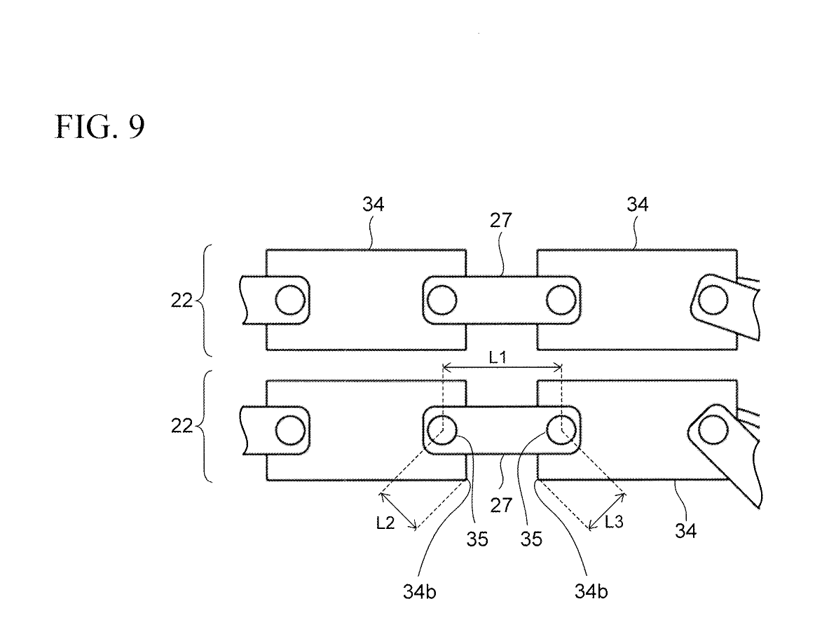

FIG. 9 is a top view of the replacement units 22.

In FIG. 9, the distance between the centers of the guide protrusions 35 on each joint 27 is denoted by L1. Also, the distance between the center of each guide protrusion 35 and a corner 34b of the housing 34 closest to that guide protrusion 35 is denoted by L2 or L3.

Each replacement unit 22 bends along the corner portions C (see FIG. 7) of the guide rails 36 when passing through the corner portions C. If the adjacent housings 34 interfere with each other during this movement, the replacement unit 22 does not pass through the corner portions C.

Thus, L1>L2+L3 is preferably satisfied so that the interference between the housings 34 may be prevented and the replacement unit 22 may smoothly pass through the corner portions C.

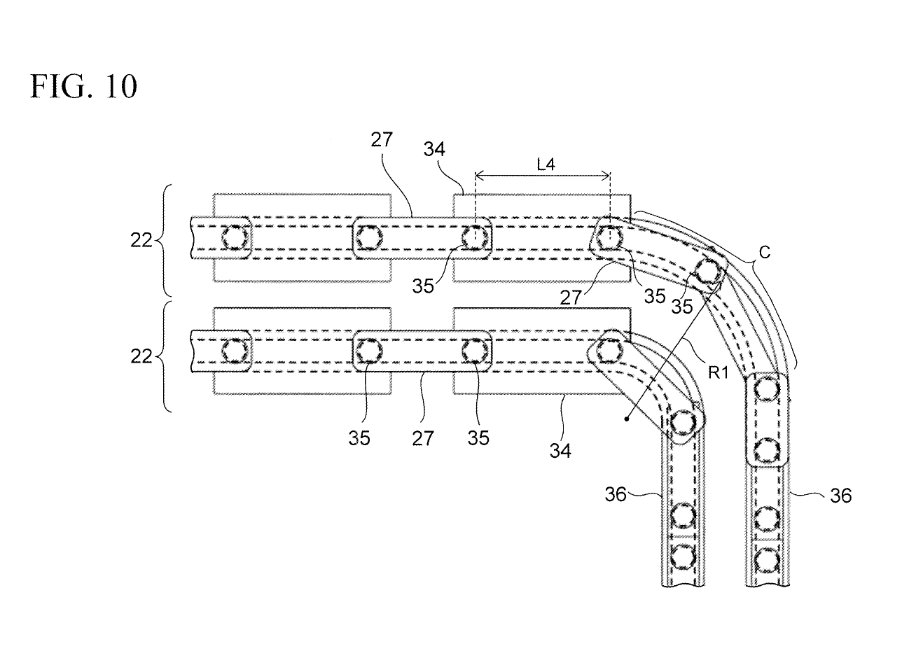

FIG. 10 is a top view of the replacement units 22 and the guide rails 36.

In FIG. 10, the radius of curvature of the corner portion C of each guide rail 36 is denoted by R. Also, the distance between the centers of the guide protrusions 35 on each housing 34 is denoted by L4.

Here, if the radius of curvature R is small, the housing 34 will be caught on the corner portions C, and the movement of the housing 34 will be obstructed. For this reason, R≧2^{-1/2}×L4 is preferably satisfied so that each pair of guide protrusions 35 on one housing 34 may be always situated in the corner portions C and the housing 34 may thus smoothly pass through the corner portions C.

Next, a method of replacing a replacement unit 22 according to this embodiment will be described.

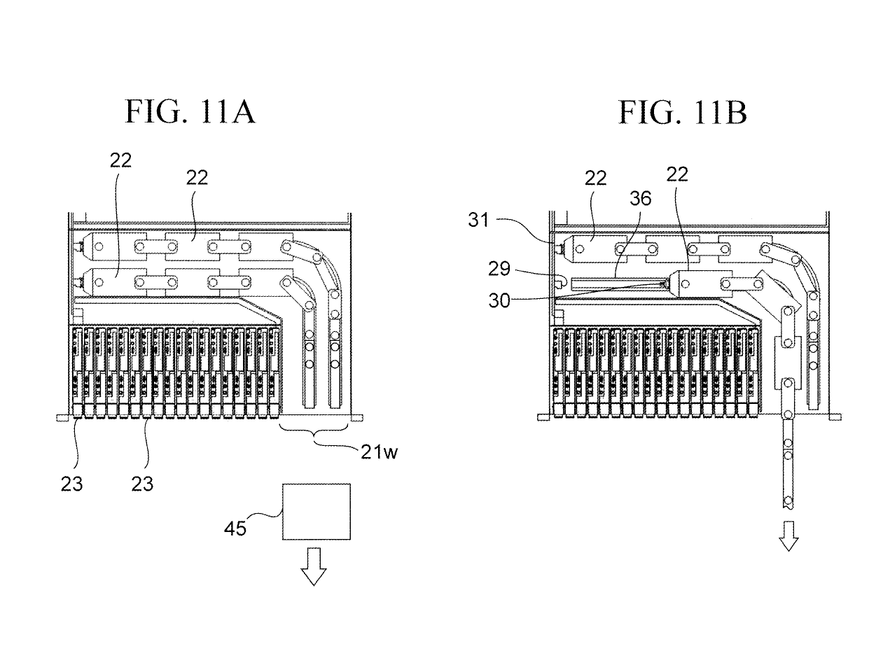

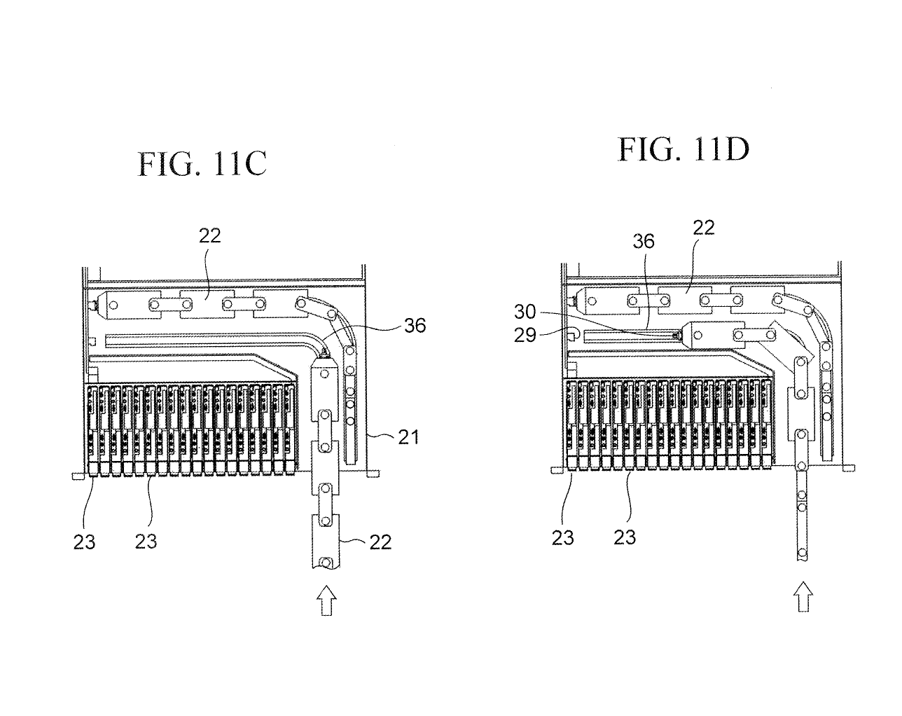

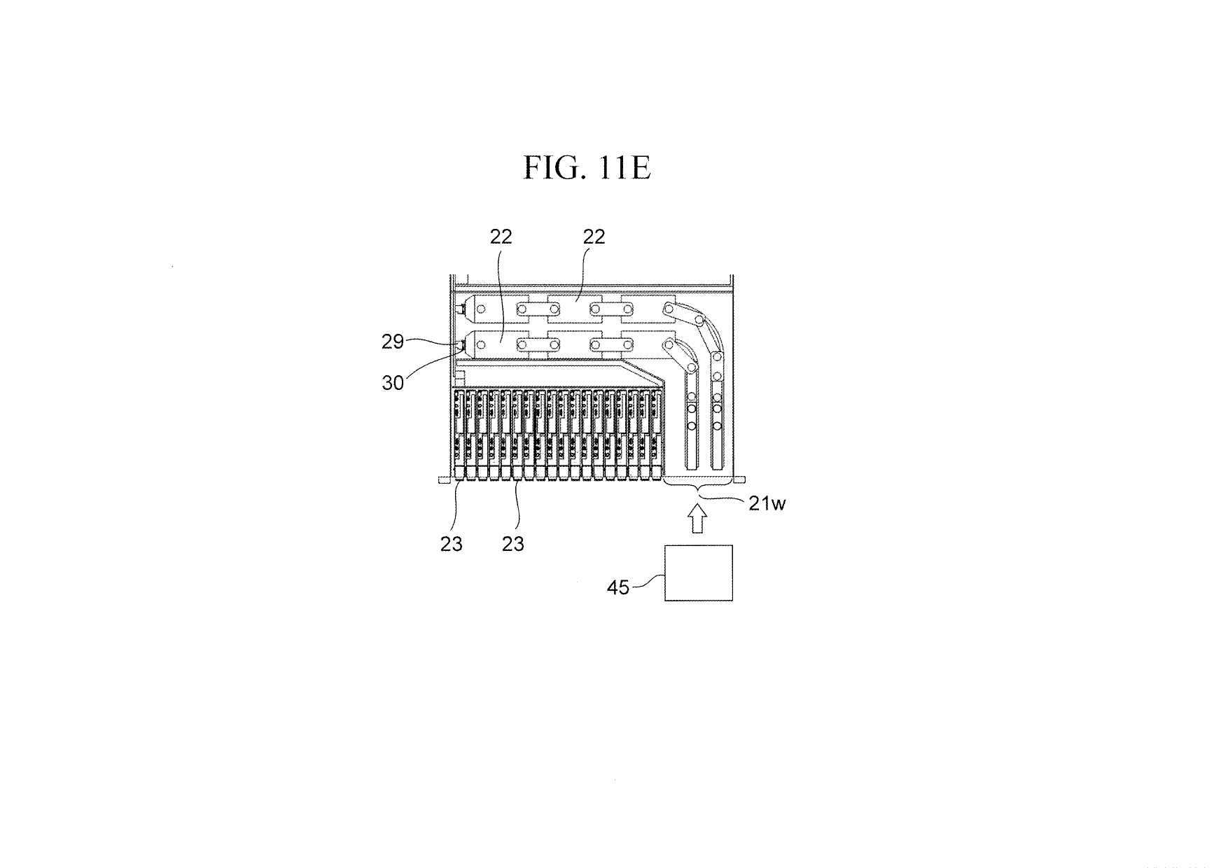

FIGS. 11A to 11E are plan views for describing the method of replacing a replacement unit 22.

First, as illustrated in FIG. 11A, the cover 45 is removed from the opening 21w of the enclosure 21.

Then, as illustrated in FIG. 11B, the operator grips the grip part 28 (see FIG. 4) of the replacement unit 22 at the front row and pulls the replacement unit 22. As a result, the second connector 30 of the replacement unit 22 at the front row is detached from the corresponding first connector 29, and the replacement unit 22 is moved along the corresponding guide rails 36.

In this step, electric power is supplied the replacement unit 22 at the rear row from the back panel 31, so that the fans 26 (see FIG. 4) of this replacement unit 22 keep rotating. Thus, cooling air may be continuously supplied to the electronic component 24 (see FIG. 3) from these fans 26. Accordingly, the replacement unit 22 which is subject to replacement may be replaced without stopping the information processing apparatus 20.

Note that once the replacement unit 22 at the front row is completely pulled out of the enclosure 21, the cover is preferably fitted to the opening 21w so that the cooling air generated by the replacement unit 22 at the rear row may be prevented from leaking through the opening 21w.

Then, once the replacement unit 22 at the front row is completely pulled out of the enclosure 21, the operator fits a new replacement unit 22 to the guide rails 36, as illustrated in FIG. 11C.

Further, as illustrated in FIG. 11D, that replacement unit 22 is pushed in.

Then, as illustrated in FIG. 11E, the replacement unit 22 is pushed further in to fit the first connector 29 and the second connector 30 to each other. The replacement work of the replacement unit 22 is finished by then fitting the cover 45 to the opening 21w of the enclosure 21

Note that the replacement unit 22 at the rear row may be replaced in a similar manner.

As described above, in this embodiment, the two bendable replacement units 22 are provided at the front row and the rear row and are fitted to the substantially L-shaped guide rails 36. In this way, one of the replacement units 22 may be driven inside the enclosure 21 while the other may be removed from the inside of the enclosure 21 to the outside.

Meanwhile in the step in FIG. 11E, the operator pushes the replacement unit 22 into the enclosure 21 to fit the first connector 29 and the second connector 30 to each other.

The degree of force to fit the connectors 29, 30 to each other will be described next.

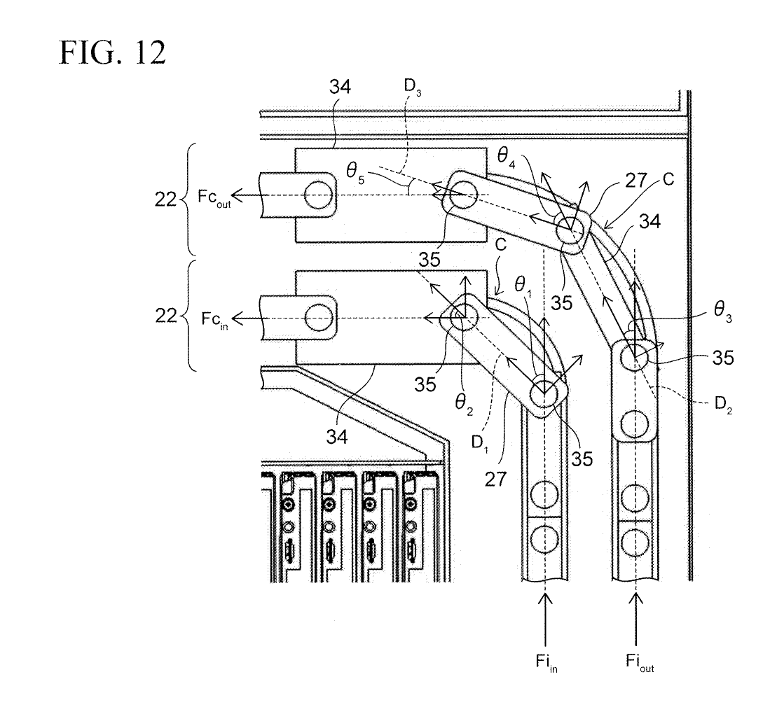

FIG. 12 is a view schematically illustrating forces applied to parts of the replacement units 22 when the replacement units 22 are pushed into the enclosure 21.

In FIG. 12, Fiᵢₙ denotes a force with which the operator pushes the replacement unit 22 at the front row. Also, Fcᵢₙ denotes a force applied from the second connector (see FIG. 4) of the replacement unit 22 at the front row to the corresponding first connector 29 when the force Fiᵢₙ is applied to that replacement unit 22.

Further, θ₁, θ₂ denote the interior angles between an extending direction D₁ of the joint 27 and the forces Fiᵢₙ, Fcᵢₙ, respectively.

Now, how to express the force Fcᵢₙ by using the force Fiᵢₙ will be discussed.

First, the force Fiᵢₙ is decomposed at the joint 27 situated in the corner portions C. The force Fiᵢₙ is decomposed into a force Fiᵢₙ·cos θ₁ in the extending direction D₁ of the joint 27 at one of the two guide protrusions 35 on the joint 27 closer to the opening 21w (see FIG. 3) of the enclosure 21.

Further, the force Fiᵢₙ·cos θ₁ is decomposed in a direction parallel to the force Fcᵢₙ at the other guide protrusion 35 on the joint 27 into a force Fiᵢₙ·cos θ₁·cos θ₂. Thus, Fcᵢₙ=Fiᵢₙ·cos θ₁·cos θ₂ holds eventually.

Forces may be calculated in a similar manner for the replacement unit 22 at the rear row; Fcₒᵤₜ=Fiₒᵤₜ·cos θ₃·cos θ₄·cos θ₅ holds, where Fiₒᵤₜ is a force with which the operator pushes the replacement unit 22 and Fcₒᵤₜ is a force applied from the second connector 30 of the replacement unit 22 at the rear row to the corresponding first connector 29.

Here, θ₃ is the interior angle between an extending direction D₂ of the housing 34 and the force Fiₒᵤₜ. Further, θ₄ is the interior angle between the extending direction D₂ of the housing 34 and an extending direction D₃ of the joint 27. Furthermore, θ₅ is the interior angle between the extending direction D₃ of the joint 27 and the force Fcₒᵤₜ.

Next, a case where θ₁=θ₂=45°, θ₃=26°, θ₄=45°, and θ₅=19° is assumed to estimate specific degrees of the forces Fcᵢₙ, Fcₒᵤₜ.

In this case, assuming that the forces Fcᵢₙ, Fcₒᵤₜ are each equal to 10 kgf, Fcᵢₙ=10 kgf×cos 45°×cos 45°≈5 kgf holds, and Fcₒᵤₜ=10 kgf×cos 26°×cos 45°×cos 19°≈6 kgf holds.

Thus, each first connector 29 and its corresponding second connector 30 are pressed against each other at a load of about 5 kgf to 6 kgf. This much of load is large enough to fit the connectors 29, 30 to each other.

According to this embodiment described above, the plurality of replacement units 22 each including fans 26 and joints 27 bendably coupled to each other are fitted to the plurality of guide rails 36. In this way, at least one of the replacement units 22 may be driven in the enclosure 21 while the rest of the replacement units 22 may be removed from the inside of the enclosure 21 to the outside.

In addition, the replacement units 22 and the information processing apparatus 20 are connected by the first and second connectors 29, 30, without using any cables to connect the replacement units 22 and the information processing apparatus 20. This prevents signal delays due to cables 4, 17 as in the examples in FIG. 1 and FIG. 2. Accordingly, the signal processing speed in the information processing apparatus 20 may be increased.

### Second Embodiment

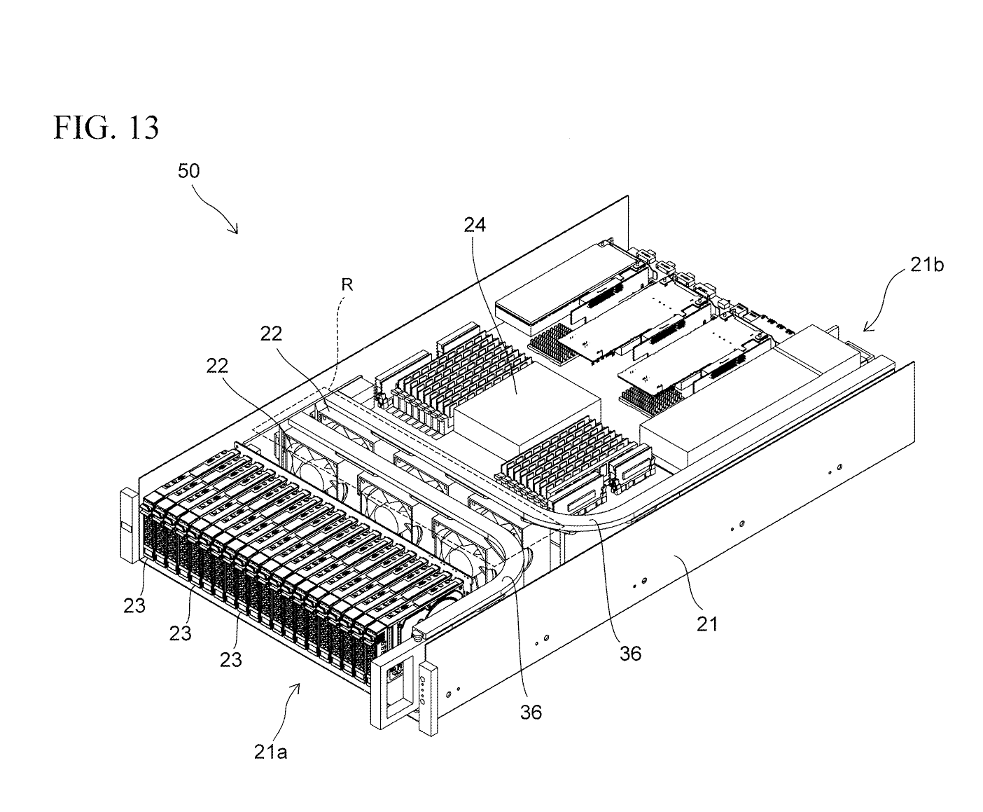

FIG. 13 is a perspective view of an information processing apparatus according to this embodiment.

In FIG. 13, the same elements as those described in the first embodiment are denoted by the same reference numerals in the first embodiment, and description thereof will be omitted below.

As illustrated in FIG. 13, in an information processing apparatus 50 according to this embodiment, one of two guide rails 36 extends in a substantially L-shape inside an enclosure 21 from a front face 21a side of the enclosure 21, while the other of the two guide rails 36 extends in a substantially L-shape inside the enclosure 21 from a back face 21b side of the enclosure 21.

Note that the upper guide rails 36 are visible in FIG. 13, but the guide rails 36 are each provided as a pair of upper and lower guide rails as in the example in FIG. 7.

Moreover, as in the first embodiment, replacement units 22 are fitted to the two pairs of guide rails 36. Further, the replacement units 22 face each other in a partial region R. Thus, even when one of the replacement units 22 is removed from the enclosure 21, the other replacement unit 22 may generate cooling air and cool the electronic component 24 with the cooling air.

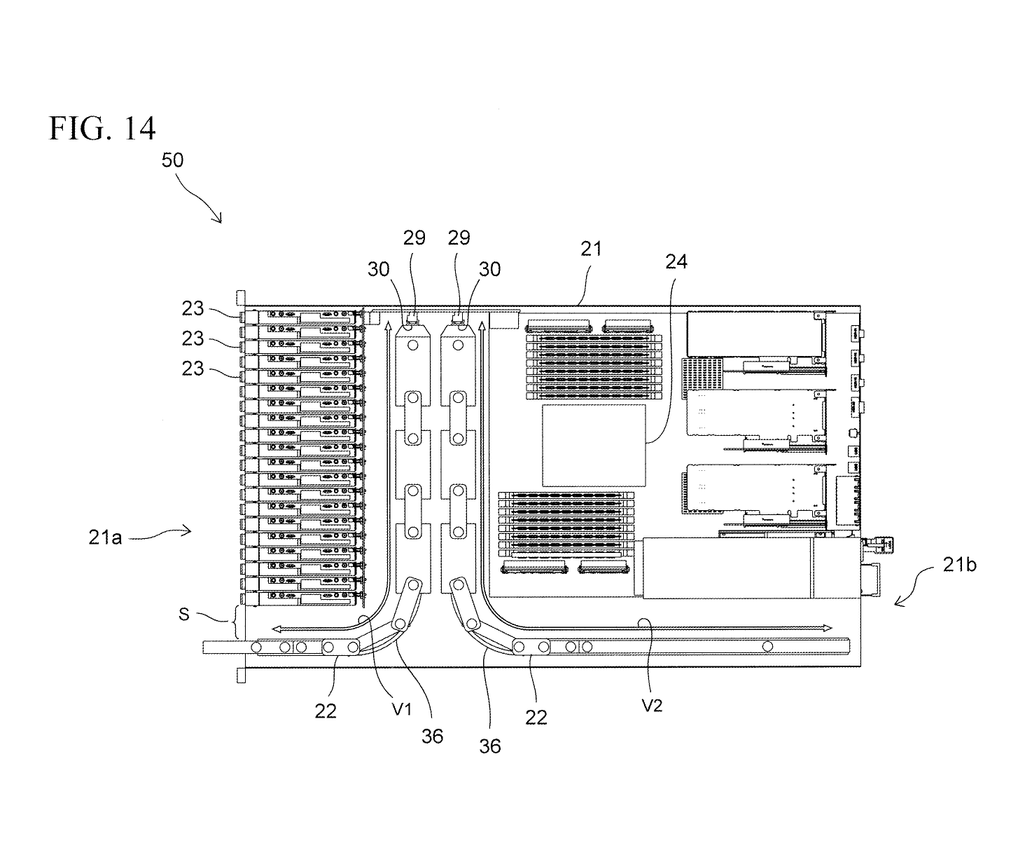

FIG. 14 is a top view of the information processing apparatus 50 without the upper ones of the upper and lower guide rails 36.

As illustrated in FIG. 14, one of the two replacement units 22 is configured to be moved along its guide rails 36 in the direction of an arrow V1 and guided to the inside of the enclosure 21 from the front face 21a side of the enclosure 21. Moreover, the other replacement unit 22 is configured to be moved along its guide rails 36 in the direction of an arrow V2 and guided to the inside of the enclosure 21 from the back face 21b side of the enclosure 21.

As described above, since at least one of the plurality of replacement units 22 are configured to be inserted into the enclosure 21 from the back face 21b side, an empty space S may be formed on the front face 21a side of the enclosure 21. In this way, hard disks 23 may be added in the empty space S. Accordingly, the space inside of the enclosure 21 may be used effectively.

### Third Embodiment

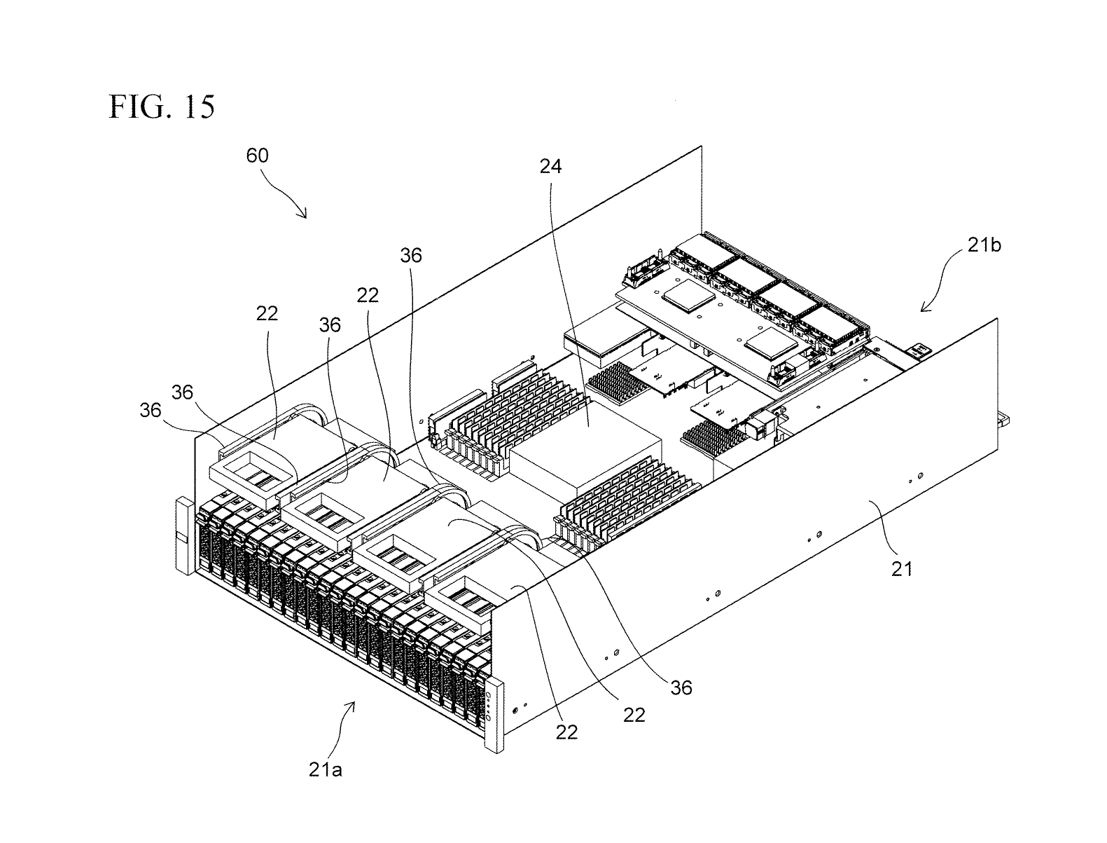

FIG. 15 is a perspective view of an information processing apparatus according to this embodiment.

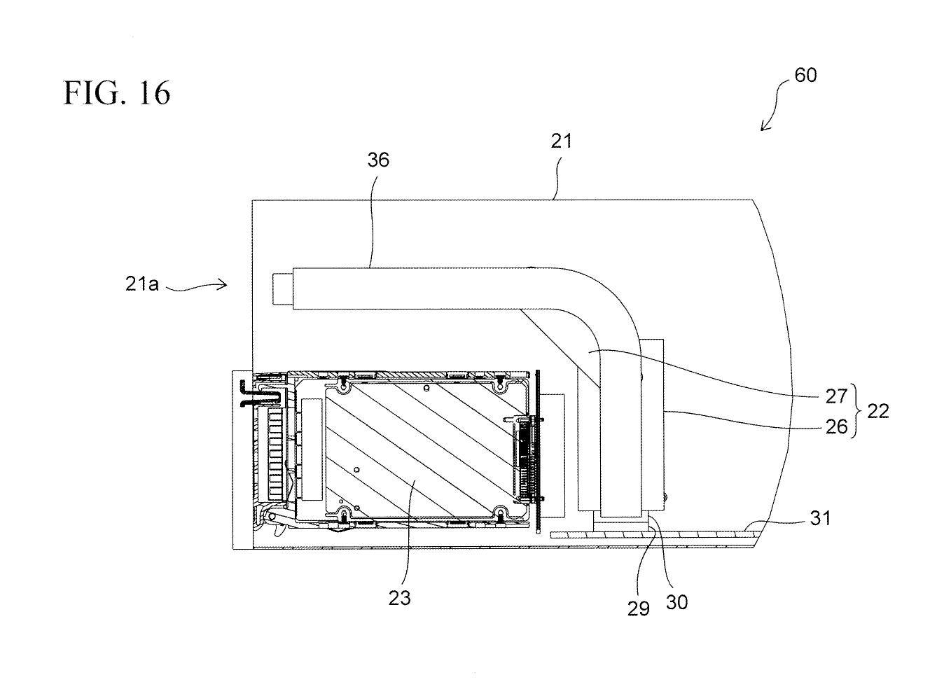

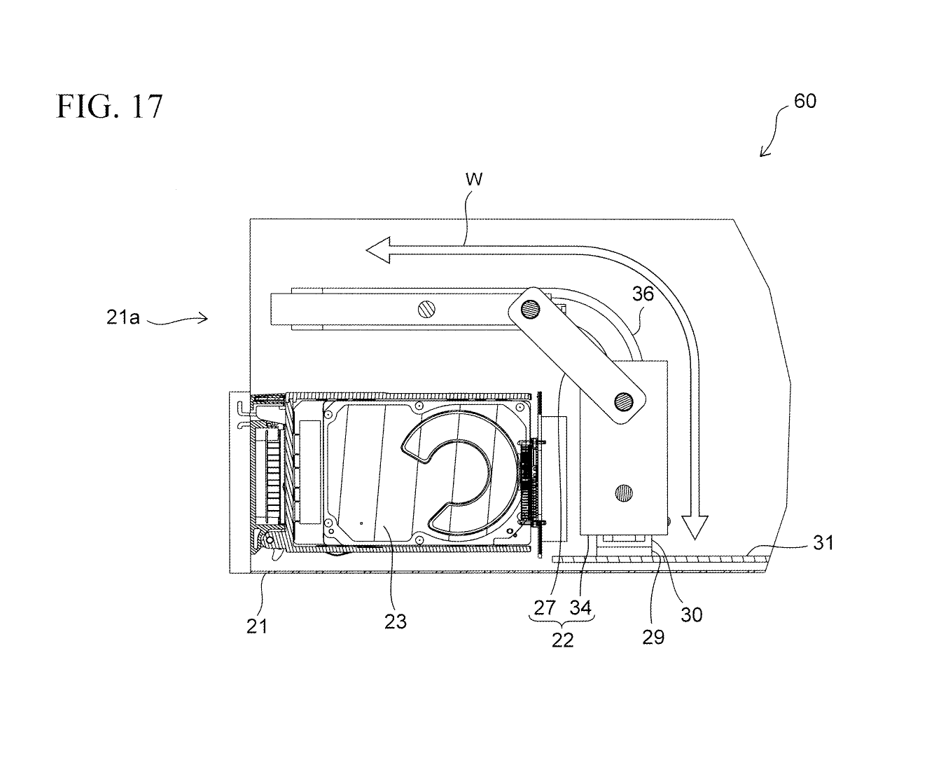

Note that in FIG. 15, the same elements as those described in the first embodiment and the second embodiment are denoted by the same reference numerals in these embodiments, and description thereof will be omitted below. The same applies also to FIG. 16 and FIG. 17 to be mentioned later.

As illustrated in FIG. 15, in an information processing apparatus 60 according to this embodiment, a plurality of replacement units 22 are provided side by side as seen from a front face 21a of an enclosure 21.

Moreover, two guide rails 36 are provided for each replacement unit 22, and the replacement unit 22 is laterally sandwiched between these guide rails 36.

FIG. 16 is a side cross-sectional view of part of this information processing apparatus 60.

As illustrated in FIG. 16, each guide rail 36 has a substantially L-shape bent downward from the upper side of the enclosure 21.

Moreover, one straight portion of the substantially L-shaped guide rail 36 is parallel to the front face 21a of the enclosure 21, while the other straight portion is perpendicular to the front face 21a.

FIG. 17 is a side cross-sectional view of part of the information processing apparatus 60 without one of the two guide rails 36 provided to each replacement unit 22.

As illustrated in FIG. 17, each replacement unit 22 may be moved along its substantially L-shaped guide rails 36 in the direction of an arrow W and inserted into and pulled out of the enclosure 21 from the front face 21a side thereof.

To replace a replacement unit 22 in this embodiment, that one of the plurality of replacement units 22 is removed from the enclosure 21, while the rest of the replacement units 22 is left inside the enclosure 21 and kept being driven.

In this embodiment, the replacement units 22 are arranged side by side in a front view of the enclosure 21 as illustrated in FIG. 15. Thus, cooling air generated by the replacement units 22 left inside the enclosure 21 as mentioned above spreads laterally inside the enclosure 21.

Thus, even when any of the plurality of replacement units 22 is removed for replacement, cooling air generated by the rest of the replacement units 22 spreads inside the enclosure 21, and the electronic component 24 may be cooled by the cooling air.

### Fourth Embodiment

In this embodiment, a grip part 28 is made detachably attachable to a replacement unit 22 in the following way.

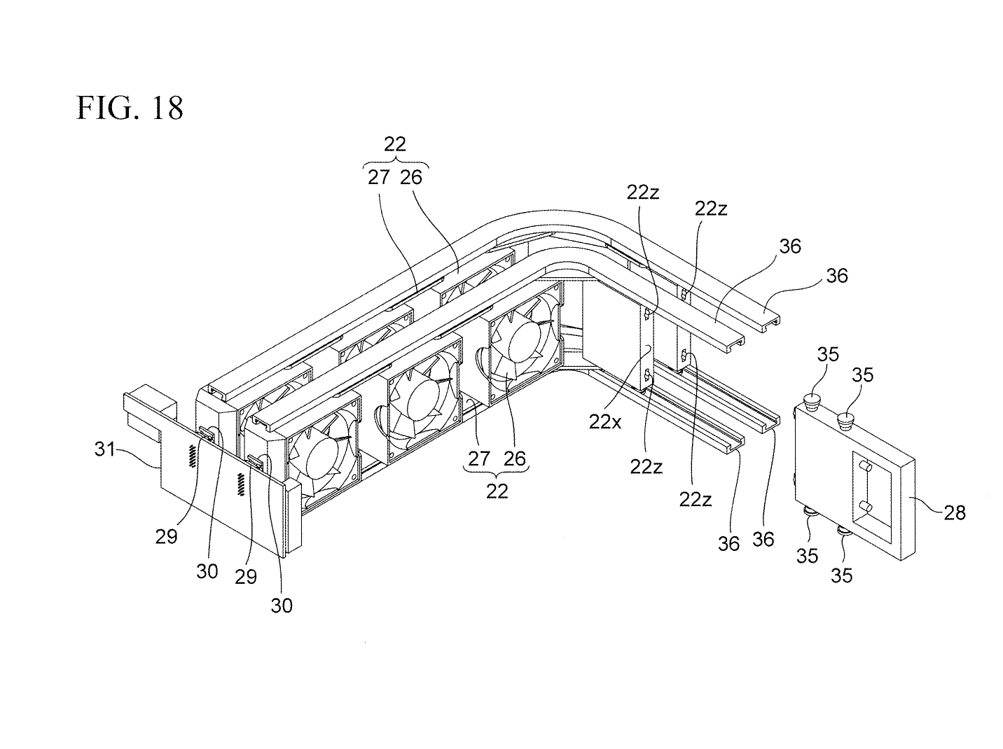

FIG. 18 is a perspective view of replacement units and their peripheral parts according to this embodiment.

Note that in FIG. 18, the same elements as those described in the first to third embodiments are denoted by the same reference numerals in these embodiments, and description thereof will be omitted below.

As illustrated in FIG. 18, lock holes 22z are provided at a proximal end 22x of each replacement unit 22 according to this embodiment. As will be described later, by fitting the grip part 28 to the lock holes 22z, the grip part 28 may be attached to the replacement unit 22.

Moreover, guide protrusions 35 configured to be fitted to guide rails 36 are fixed to the grip part 28.

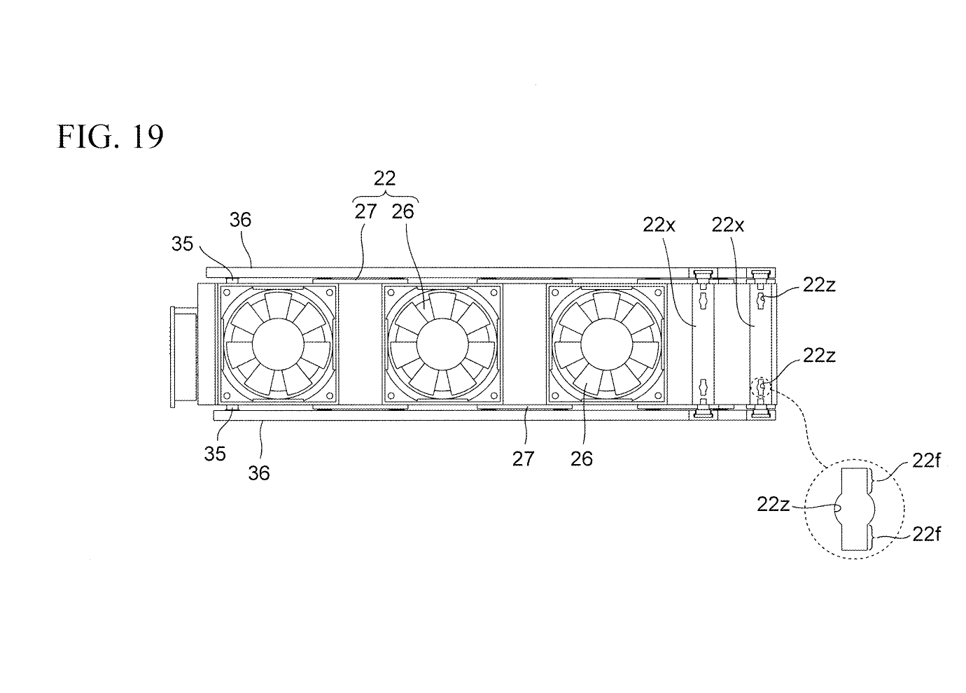

FIG. 19 is a front view of the replacement units 22.

As illustrated inside the dotted circle in FIG. 19, each lock hole 22z has protruding portions 22f protruding from the center thereof.

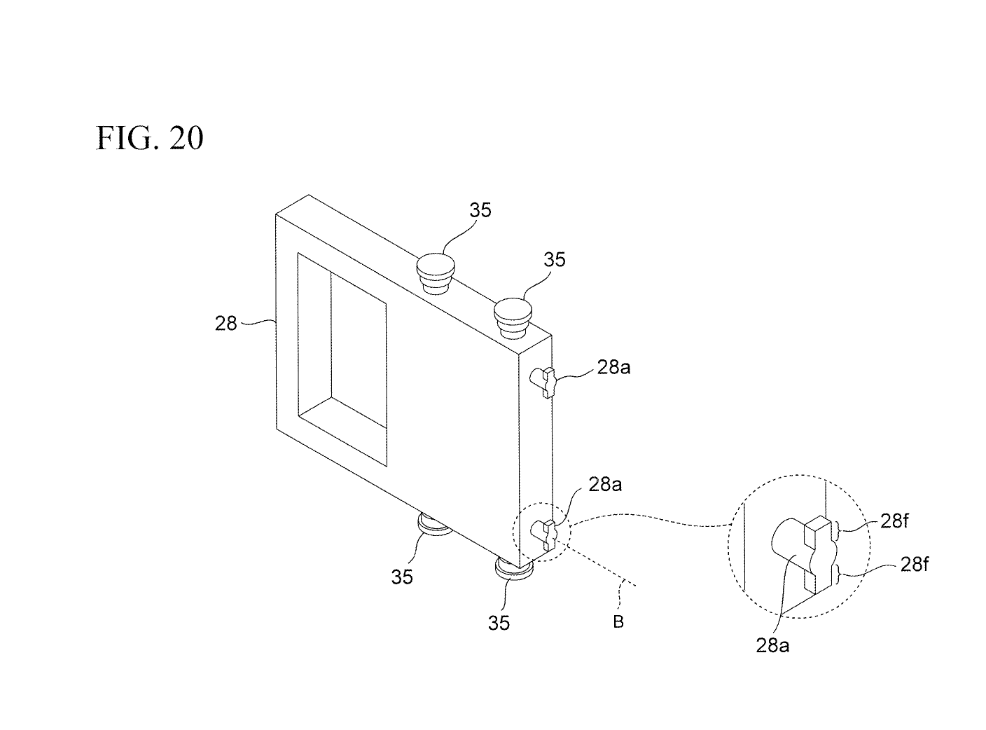

FIG. 20 is a perspective view of the grip part 28.

As illustrated in FIG. 20, protrusions 28a each capable of rotation about an axis B are provided on the grip part 28. Locking pieces 28f are formed on each protrusion 28a, and the grip part 28 is fixed to the replacement unit 22 by rotating the protrusions 28a by about 90° with the locking pieces 28f inserted in the protruding portions 22f (see FIG. 19).

Note that the grip part 28 may be detached from the replacement unit 22 by performing these operations in reverse order.

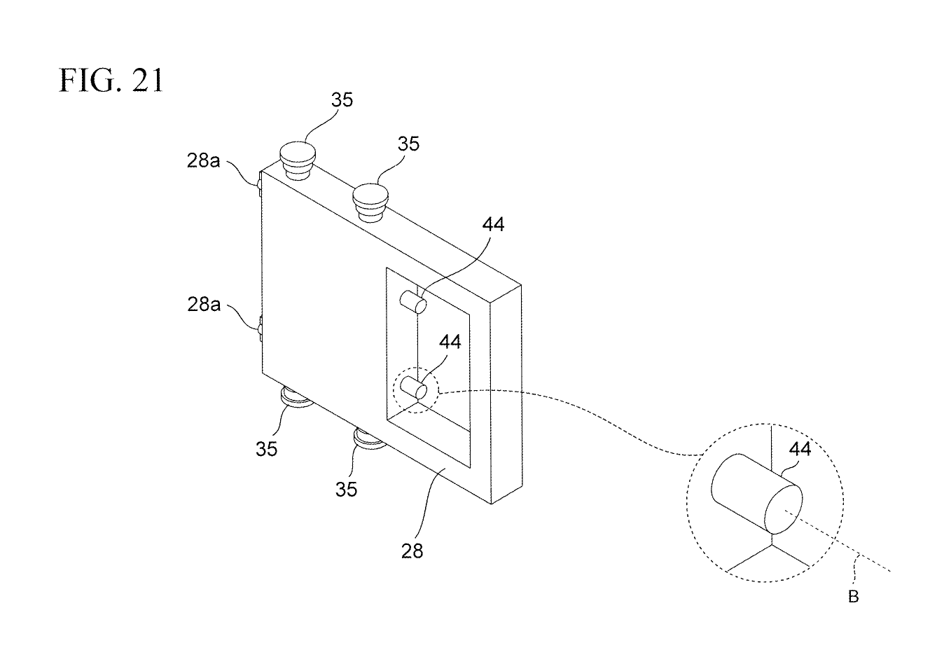

FIG. 21 is a perspective view of the grip part 28 as seen from a different angle from FIG. 20.

As illustrated in FIG. 21, substantially cylindrical handle locks 44 are provided to the grip part 28. The handle locks 44 are connected to the protrusions 28a. As the operator rotates the handle locks 44 about the axes B, the protrusions 28a rotate as well such that the grip part 28 may be attached to and detached from the replacement unit 22.

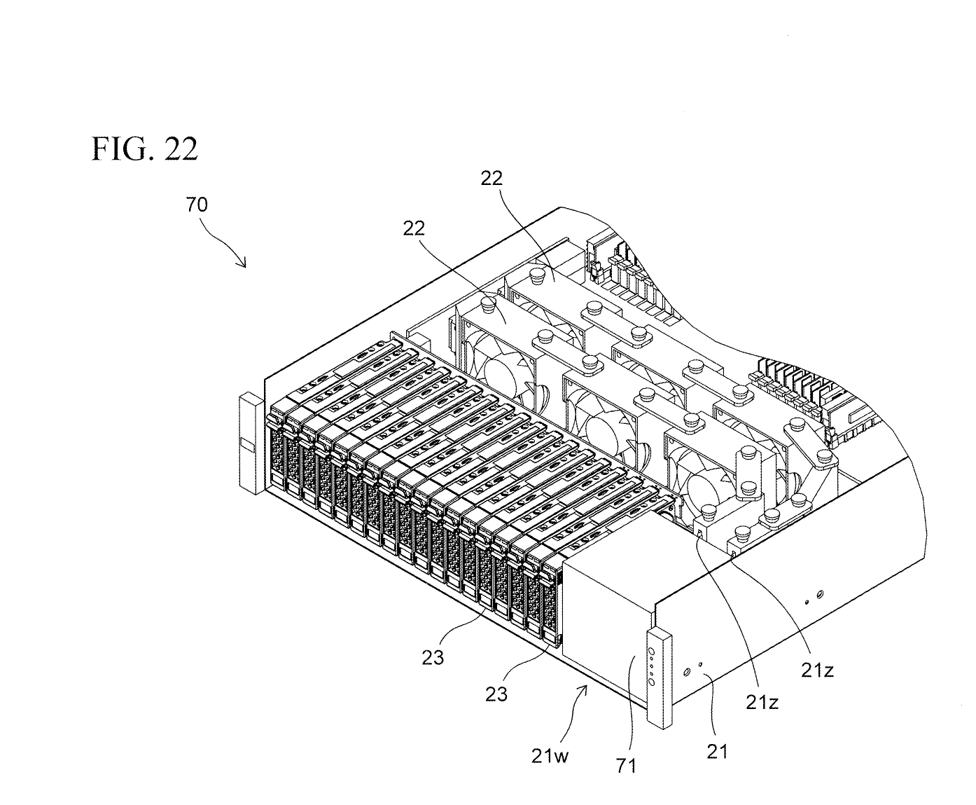

FIG. 22 is an enlarged perspective view of an information processing apparatus 70 according to this embodiment.

Note that in FIG. 22, the same elements as those described in the first to third embodiments are denoted by the same reference numerals in these embodiments, and description thereof will be omitted below.

In this embodiment, the grip part 28 is attached to a replacement unit 22 which is subject to replacement when replacement work of that replacement unit 22 is performed. The grip part 28 is detached from the replacement unit 22 in other situations.

The absence of the grip part 28 accordingly allows an empty space near an opening 21w of an enclosure 21, and an operation part 71 may be attached in this empty space. The operation part 71 is a user interface with which the information processing apparatus 70 is powered on and the electronic component 24 is operated. By attaching such an operation part 71 to the enclosure 21, the operability of the information processing apparatus 70 improves.

### Fifth Embodiment

In this embodiment, the burden on the user in inserting and pulling a replacement unit 22 into and out of an enclosure 21 is reduced in the following way.

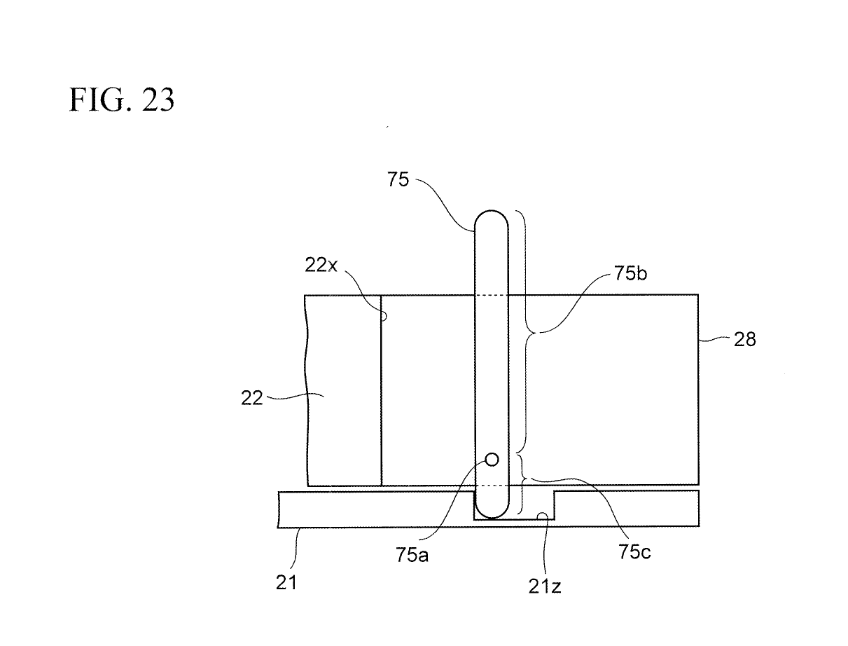

FIG. 23 is an enlarged side view of a replacement unit 22 according to this embodiment.

As illustrated in FIG. 23, in this embodiment, a lever 75 is provided to a grip part 28 of the replacement unit 22.

The lever 75 is turnable about a pivot point 75a, and includes an arm 75b for the operator to grip and a fitting portion 75c shorter than the arm 75b. Moreover, a concave portion 21z configured to be fitted to the fitting portion 75c is provided to the enclosure 21.

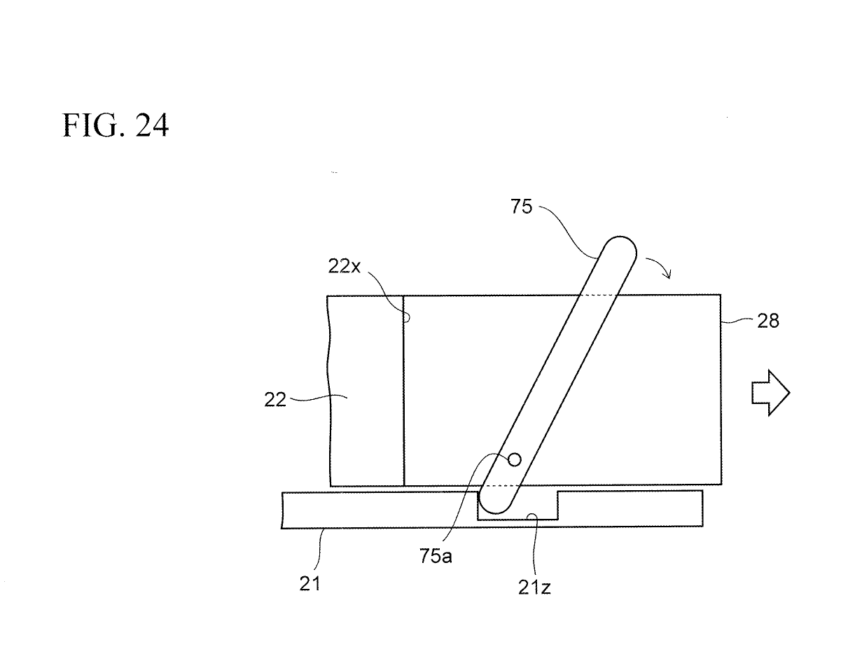

FIG. 24 is an enlarged side view of the replacement unit 22 after the operator turns the lever 75.

As illustrated in FIG. 24, as the lever 75 is turned, the grip part 28 slides on the enclosure 21. In this way, the replacement unit 22 may be inserted into and pulled out of the enclosure 21.

In particular, by making the arm 75b longer than the fitting part 75c as in this example, the force which the operator applies to the arm 75b may be reduced by the principle of leverage. Thus, the burden on the operator may be reduced.

Thus, the replacement unit 22 may be easily inserted into and pulled out of the enclosure 21 even in a case where the force to connect and disconnect the first connector 29 (see FIG. 4) and the second connector 30 exceeds levels of force which a man may apply (approximately 20 kgf).

### Sixth Embodiment

In this embodiment, insufficient cooling inside an enclosure is prevented in the following way.

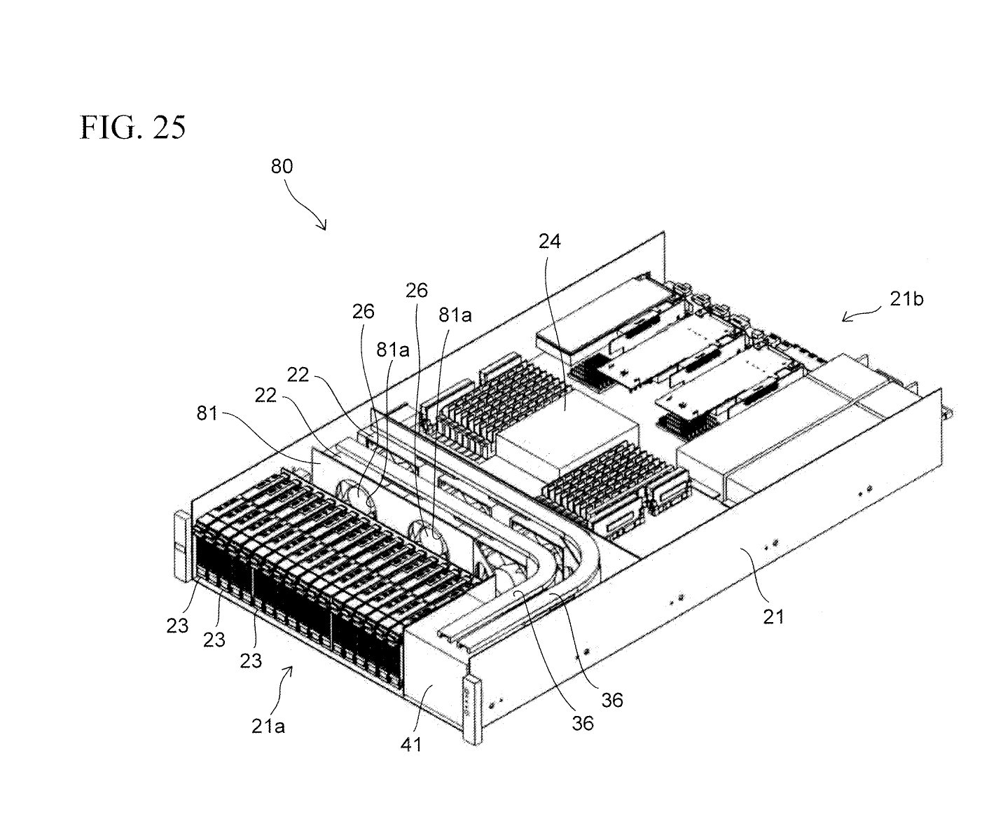

FIG. 25 is a perspective view of an information processing apparatus 80 according to this embodiment.

Note that in FIG. 25, the same elements as those described in the first to fifth embodiments are denoted by the same reference numerals in these embodiments, and description thereof will be omitted below.

As illustrated in FIG. 25, in this embodiment, of the replacement units 22 at the front row and the rear row described in FIG. 3 in the first embodiment, the replacement unit 22 at the front row is provided with a partition plate 81 in front thereof. The other features of the structure are the same as those of the first embodiment.

The partition plate 81 has a plurality of openings 81a facing fans 26 in one-to-one correspondence, and the flow of cooling air generated by the replacement units 22 is regulated at each opening 81a.

This prevents cooling air generated by one fan 26 from flowing to its neighboring fans 26 or cooling air from being disturbed near each fan 26. Accordingly, an electronic component 24 may be cooled efficiently by the cooling air.

Note that such a partition plate 81 is applicable not only to the first embodiment but also to the second embodiment and the third embodiment.

All examples and conditional language recited herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An information processing apparatus, comprising:
an enclosure;
a plurality of replacement units each provided inside the enclosure and including a component and a joint bendably coupled to each other; and
a plurality of guide rails which are provided inside the enclosure for each of the plurality of replacement units and to which the replacement unit is fitted.

2. The information processing apparatus according to claim 1, further comprising:
a first connector fixed inside the enclosure; and
a second connector provided at a distal end of the replacement unit and configured to be fitted to the first connector.

3. The information processing apparatus according to claim 1, wherein the component is a fan.

4. The information processing apparatus according to claim 3, wherein the plurality of replacement units face each other in a partial region inside the enclosure.

5. The information processing apparatus according to claim 3, further comprising:
a partition plate including an opening facing the component.

6. The information processing apparatus according to claim 1, wherein
one of the plurality of guide rails guides the replacement unit into the enclosure from a front face of the enclosure, and
the rest of the plurality of guide rails guides the replacement unit into the enclosure from a back face of the enclosure.

7. The information processing apparatus according to claim 1, wherein the plurality of replacement units are provided side by side in a front view of the enclosure.

8. The information processing apparatus according to claim 1, wherein a detachable grip part is provided at a proximal end of the replacement unit.

9. The information processing apparatus according to claim 1, wherein
an opening is provided at a front face of the enclosure, where the replacement unit passing through the opening, and
a metal cover is detachably fitted to the opening.

10. The information processing apparatus according to claim 1, wherein
an opening is provided at a front face of the enclosure, where the replacement unit passing through the opening, and
an operation part, where the operation part operating an electronic component inside the enclosure, is provided in the opening.

11. The information processing apparatus according to claim 1, further comprising:
a lever including a fitting portion and provided to the replacement unit turnably about a pivot point, wherein
a concave portion configured to be fitted to the fitting portion is formed in the enclosure.

12. A replacement unit, comprising:
a component;
a joint bendably provided to the component; and
a protrusion provided to at least one of the component and the joint and configured to be fitted to a guide rail of an information processing apparatus.

13. The replacement unit according to claim 12, wherein a second connector configured to be fitted to a first connector fixed to the information processing apparatus is provided at a distal end of the replacement unit.

14. The replacement unit according to claim 12, wherein a detachable grip part is provided at a proximal end of the replacement unit.

15. The replacement unit according to claim 12, wherein
a plurality of the components are provided, and
the plurality of components are coupled to each other by the joint.

16. The replacement unit according to claim 12, wherein the component is a fan.
